(19) United States
(12) Patent Application Publication
(10) Pub. No.: US 2020/0350142 A1
(43) Pub. Date: Nov. 5, 2020

(54) LOW-TEMPERATURE IONIZATION OF METASTABLE ATOMS EMITTED BY AN INDUCTIVELY COUPLED PLASMA ION SOURCE

(71) Applicant: ZEROK NANO TECH CORPORATION, Gaithersburg, MD (US)

(72) Inventors: Brenton J. KNUFFMAN, Gaithersburg, MD (US); Adam V. STEELE, Clarksburg, MD (US)

(21) Appl. No.: 16/764,968

(22) PCT Filed: Nov. 20, 2018
(86) PCT No.: PCT/US2018/062119

§ 371 Date: May 18, 2020

Related U.S. Application Data
(60) Provisional application No. 62/589,117, filed on Nov. 21, 2017.

(51) Int. Cl. H01J 37/32

(52) U.S. Cl. CPC H01J 37/32422; H01J 37/32339; H01J 37/3211

(57) ABSTRACT

The present disclosure combines inductively coupled plasma (ICP) ion-source technology together with laser-cooling and photoionization techniques to create a new ion source that has improved performance.

### BACKGROUND OF THE INVENTION

### Field of the Invention

The present invention relates to methods and systems for generating ion beams.

### Description of the Background

Ion sources employing inductively coupled plasma technology are well known in the art, see, e.g., U.S. Pat. No. 8,829,468 B2. As used herein, an Inductively Coupled Plasma Ion Source (ICP) is an inductively coupled plasma from which ions may be extracted using an electric field and from which a variety of neutral particles may also be emitted. The ICP is typically used for the production of high-current ion beams of noble-gas atomic species (e.g: Ne, Ar, Kr, Xe).

When integrated with focused ion beam (FIB) instruments, the ICP is most effective at tasks requiring larger-scale removal of material owing to its ability to produce an ion beam with a large amount of current. However, one significant limitation of the ICP is its inability to provide an ion beam that may be focused to small spot sizes, when compared with other ion sources used in the art. This limitation makes this source poorly suited to precise removal or modification of smaller volumes of material. This limitation also makes difficult using the ICP for the creation of creation of thin, highly-polished sections of material (lamellae); such lamellae are often used as samples in transmission electron microscopy.

It is known in the art that the ICP, in addition to emitting ions, also emits so-called ‘metastable’ neutral particles (atoms most often). A metastable atom is an atom in a relatively-long-lifetime (milliseconds or greater) internal state other than its ground state. In some species metastable atoms behave very differently under the influence of laser light than their ground-state analogs. Metastable atoms of noble gas species are much more amenable to the application of laser-cooling and photoionization techniques than their ground state analogs. In focused ion beam systems employing an ICP today these metastable neutral particles are not utilized and a variety of techniques are utilized to filter them from the output and discard them.

It is known in the art that laser beams can induce velocity or position dependent forces on atoms (including metastable atoms); these forces may be modified by the addition of magnetic fields. These forces can be applied to populations of particles to slow (reduce average velocity), cool (reduce variance in velocity), or compress (reduce variance in position). Additionally, laser radiation applied to atoms may create conservative force fields, for example in the case of a dipole trap. These techniques are known collectively in the art and in the present disclosure as Laser Cooling and Trapping (LCT).

It is known in the art that light (lasers typically) can be used to ionize atoms through a process called photoionization. Photoionization describes the illumination of particles with one or more beams of light that have sufficient energy to ionize via the absorption of one or more photons.

### SUMMARY OF THE INVENTION

The present disclosure improves the utility of the ICP by providing a system and method for generation of ions derived from ICP-emitted metastable atoms. More specifically, the present invention couples the ICP with laser-cooling and photoionization laser beams. When metastable atoms are emitted from the ICP, they are illuminated by laser beams to compress their phase-space volume (reduce their temperature and compress them in space), and then photoionize them. Ions generated through such a process of cooling and photoionization may be more readily focused into small spot sizes than the ions emitted from the ICP alone.

Accordingly, the present invention relates to an ion source that converts the metastable neutral atoms emitted from an inductively coupled plasma source into a high-brightness, low-energy-spread beam of ions.

The ion source of the present disclosure utilizes a standard ICP that is known in the art to emit both ions and metastable neutral atoms. The invention engages laser cooling and trapping and photo-ionization techniques on ICP-emitted metastable neutral atoms to create a secondary ion beam.

The ion source may be operated in one of several modes:
1. Normal Mode Only: where the ions from the ICP are used, and the emitted metastable atoms (or metastable-derived photoionized particles) discarded,
2. Enhanced Normal Mode Only: where one or more beams of laser radiation are directed into the discharge vessel to change the character of the metastable atoms being emitted from the ICP, and/or to increase the brightness of the ions emitted from the ECP; and
3. Cold-Ion Modes (a) and (b):
   a. Taking metastable atoms emitted from a Normal Mode ICP, and cooling and photoionizing them into an ion beam;
   b. Taking metastable atoms emitted from an Enhanced Normal Mode ICP, and cooling and photoionizing them into a focused ion beam;

The laser cooling and photoionization of metastable atoms may operate continuously even when in Normal Mode, but the ions generated from photoionization will not necessarily be used.

There is significant utility in this invention's ability to provide a single ion source with a mode-selectable ion beam that can be optimized to the task at hand. Ion beams created from the metastable atoms (Cold-Ion Mode) typically have a higher brightness and lower energy spread than ions directly created by the ICP. For this reason ions generated in Cold-Ion Mode may be focused to smaller spot sizes, albeit typically at lower beam currents, than the beam used in Normal Mode. This makes the metastable-derived (Cold-Ion Mode) ion beam better suited for precise removal of smaller volumes of material (cubic nm to a few cubic microns), or final polishing of thin samples, than the ion beam generated by the ICP (Normal Mode). While providing the ability to operate in Cold-Ion mode, the invention retains its ability to work in Normal Mode, where the capacity of the source to perform well at larger scale material removal tasks are well-established in the art. The operation of the source in Normal Mode may also be enhanced (“Enhanced Normal Mode”) through the application of laser cooling to the neutral gas within the discharge vessel.

The result of the invention is an ion source with high performance over a wide range of beam currents, from pico-Amperes to micro-Amperes.

Accordingly, there is provided according to an embodiment of the invention an ion source system, including an inductively coupled plasma (ICP) source, wherein metastable atoms and ions are generated within a plasma vessel; the ion source system having a first mode and a second mode for producing an ion beam from the metastable atoms and the ions generated in the plasma vessel; wherein the first mode further includes metastable atoms emitted from the plasma vessel; one or more beams of laser radiation are configured to excite the emitted metastable atoms to form ions; and charged particle optics are configured to accelerate the emitted or extracted ions to form the ion beam; and wherein the second mode includes ions emitted or extracted from the plasma vessel; charged particle optics are configured to accelerate the emitted or extracted ions to form the ion beam; and charged particle optics are configured to condition the ion beam for use in focused ion beam instrumentation.

There is also provided according to a further embodiment of the invention an ion source system additionally including one of more beams of laser radiation configured to cool or compress the metastable atoms emitted from the plasma vessel.

There is also provided according to a further embodiment of the invention an ion source system additionally including a magnetic field applied in the vicinity of the one of more beams of laser radiation configured to cool or compress the metastable atoms emitted from the plasma vessel.

There is also provided according to a further embodiment of the invention an ion source system additionally including one or more beams of laser radiation applied to the metastable atoms contained inside the plasma vessel.

There is also provided according to a further embodiment of the invention an ion source system additionally including a magnetic field inside the plasma vessel configured to mediate the interaction of the metastable atoms and the one of more beams of laser radiation applied to the metastable atoms contained inside the plasma vessel.

There is also provided according to a further embodiment of the invention an ion source system wherein the beams of laser radiation excite a resonant ionization process in the electric field

There is also provided according to a further embodiment of the invention an ion source system wherein the beams or laser radiation excite the metastable atoms to Rydberg states that subsequently ionize in the electric field.

There is also provided according to a further embodiment of the invention an ion source system additionally including the introduction of an additional gas species to the plasma vessel to enhance the production of metastable atoms.

There is also provided according to a further embodiment of the invention an ion source system including an inductively coupled plasma (ICP) source, wherein metastable atoms and ions are generated within a plasma vessel; one or more beams of laser radiation are configured to cool or compress the metastable atoms contained inside the plasma vessel; ions are emitted or extracted from the plasma vessel; and charged particle optics are configured to accelerate the emitted or extracted ions to form the ion beam.

There is also provided according to a further embodiment of the invention an ion source system additionally including a magnetic field inside the plasma vessel configured to mediate the interaction of the metastable atoms and the one of more beams of laser radiation applied to the metastable atoms contained inside the plasma vessel.

There is also provided according to a further embodiment of the invention a method for producing an ion source including the steps of providing an ICP source, wherein metastable atoms and ions are generated within a plasma vessel; providing a first mode and a second mode for producing an ion beam from the metastable atoms and the ions generated in the plasma vessel; wherein the first mode includes receiving metastable atoms from the plasma vessel; providing one or more beams of laser radiation configured to excite the emitted metastable atoms to form ions; providing one or more electrodes with voltages applied to create an electric field configured to accelerate the ions to form the ion beam, and wherein the second mode includes receiving ions emitted or extracted from the plasma vessel; providing charged particle optics configured to accelerate the emitted or extracted ions to form the ion beam, and providing charged particle optics configured to condition the ion beam for use in focused ion beam instrumentation

There is also provided according to a further embodiment of the invention a method for producing an ion source additionally including the step of providing one of more beams of laser radiation configured to cool or compress the metastable atoms emitted from the plasma vessel.

There is also provided according to a further embodiment of the invention a method for producing an ion source additionally including the step of providing a magnetic field applied in the vicinity of the one of more beams of laser radiation configured to cool or compress the metastable atoms emitted from the plasma vessel.

There is also provided according to a further embodiment of the invention a method for producing an ion source additionally including the step of providing one or more beams of laser radiation applied to the metastable atoms contained inside the plasma vessel.

There is also provided according to a further embodiment of the invention a method for producing an ion source additionally including the step of providing a magnetic field inside the plasma vessel configured to mediate the interaction of the metastable atoms and the one of more beams of laser radiation applied to the metastable atoms contained inside the plasma vessel.

There is also provided according to a further embodiment of the invention a method for producing an ion source, wherein the beams of laser radiation are tuned to excite a resonant ionization process in the electric field.

There is also provided according to a further embodiment of the invention a method for producing an ion source additionally including the step of providing an additional gas species to the plasma vessel to enhance the production of metastable atoms.

There is also provided according to a further embodiment of the invention a method for producing an ion source including providing an inductively coupled plasma (ICP) source wherein metastable atoms and ions are generated within a plasma vessel; including the steps of providing one or more beams of laser radiation configured to cool or compress the metastable atoms contained inside the plasma vessel; receiving ions emitted or extracted from the plasma vessel; and providing charged particle optics configured to accelerate the emitted or extracted ions to form the ion beam.

There is also provided according to a further embodiment of the invention a method for producing an ion source additionally including the step of providing a magnetic field inside the plasma vessel configured to mediate the interaction of the metastable atoms and the one of more beams of laser radiation applied to the metastable atoms contained inside the plasma vessel.

There is also provided according to a further embodiment of the invention an ion source including:

a. an inductively coupled plasma (ICP) source having
i. a plasma discharge vessel containing a gas and having a gas inlet and a plasma outlet;
ii. an antenna adjacent said discharge vessel and configured to receive an RF current; and
iii. a plurality of electrodes arranged adjacent said plasma outlet;
   and
b. a laser cooling and photoionization stage, having:
   i. a metastable atom inlet configured to receive a beam of metastable atoms from said inductively coupled plasma source;
   ii. a first set of laser emitters each configured to direct a laser beam into said beam of metastable atoms to cool and/or condense said beam of metastable atoms;
   iii. a second set of laser emitters each configured to direct a laser beam into said beam of metastable atoms to photoionize a population of said metastable atoms to produce a population of ions; and
   iv. a plurality of electrodes arranged adjacent said beam of metastable atoms configured to produce an electric field that converts said population of ions into an ion beam.

There is also provided according to a further embodiment of the invention an ion source additionally including a plurality of laser emitters each configured to direct a laser beam into said plasma discharge vessel.

There is also provided according to a further embodiment of the invention an ion source additionally including a plurality of permanent magnets configured to produce a magnetic field inside said plasma discharge vessel.

There is also provided according to a further embodiment of the invention an ion source additionally including a plurality of current-carrying wires configured to produce a magnetic field inside said plasma discharge vessel.

There is also provided according to a further embodiment of the invention an ion source additionally including a plurality of permanent magnets configured to produce a magnetic field in the vicinity of said beam of metastable atoms.

There is also provided according to a further embodiment of the invention an ion source additionally including a plurality of current-carrying wires configured to produce a magnetic field in the vicinity of said beam of metastable atoms.

There is also provided according to a further embodiment of the invention an ion source wherein the second set of laser emitters is configured to excite a resonant photoionization process in said electric field

There is also provided according to a further embodiment of the invention an ion source wherein the second set of laser emitters is configured to excite said metastable atoms to a Rydberg state that subsequently ionizes in said electric field

There is also provided according to a further embodiment of the invention an ion source additionally including a second gas contained in the plasma discharge vessel.

There is also provided according to a further embodiment of the invention a method for producing an ion beam, including:
a. generating a population of ions and metastable atoms in a plasma vessel;
b. selecting an operational mode from among a first mode and a second mode;
c. where, following selection of said first mode, the method further comprises:
   i. receiving metastable atoms from said plasma vessel;
   ii. radiating said metastable atoms with laser radiation to ionize the metastable atoms into a second population of ions;
   iii. directing said second population of ions through an electric field to form an ion beam;
d. where, following selection of said second mode, the method further comprises;
   i. directing said population ions generated in said plasma vessel through an electric field to form an ion beam.
e. where according to both said first and second modes, the resulting ion beam is treated with charged particle optics to condition the ion beam for use in focused ion beam instrumentation.

There is also provided according to a further embodiment of the invention a method for producing an ion beam additionally including the step of radiating the plasma discharge vessel with laser radiation.

There is also provided according to a further embodiment of the invention a method for producing an ion beam additionally including the step of generating a magnetic field in the plasma discharge vessel with a plurality of permanent magnets.

There is also provided according to a further embodiment of the invention a method for producing an ion beam additionally including the step of generating a magnetic field in the plasma discharge vessel with a plurality of current carrying wires.

There is also provided according to a further embodiment of the invention a method for producing an ion beam additionally including the step of generating a magnetic field in the vicinity of the beam of metastable atoms with a plurality of permanent magnets.

There is also provided according to a further embodiment of the invention a method for producing an ion beam additionally including the step of generating a magnetic field in the vicinity of the beam of metastable atoms with a plurality of current carrying wires.

There is also provided according to a further embodiment of the invention a method for producing an ion beam additionally including the step of configuring said radiation in first said mode to excite a resonant ionization process.

There is also provided according to a further embodiment of the invention a method for producing an ion beam additionally including the step of configuring said radiation in first said mode to excite a Rydberg state that subsequently ionizes in said electric field.

There is also provided according to a further embodiment of the invention a method for producing an ion beam, where an additional gas species is introduced into the plasma vessel.

### BRIEF DESCRIPTION OF THE DRAWINGS

FIG. 1 is a schematic showing primary features of an ion source according to an embodiment of the invention.

### DETAILED DESCRIPTION

A system and method are described for creation of ions utilizing an inductively coupled plasma as well as laser-cooling and photoionization laser beams.

An inductively coupled plasma ion source [100] in which a gas of metastable atoms [101] and ions are produced inside a plasma discharge vessel [102] through collisional excitation with plasma electrons. The plasma electrons are typically excited via a RF current applied to an antenna [103]. During Normal Mode operation, one or more electrodes [104-107] near the discharge vessel may be biased with selected voltages to produce, tune, or suppress a beam of ions from ions produced in the discharge vessel. The discharge vessel may be made from a transparent dielectric material.

A second gas species (other than the one from which ions are produced) may be optionally introduced to the plasma vessel [102]. It is known in the art that addition of a second gas to the plasma vessel may enhance the production or properties of metastable atoms emitted from the plasma vessel; the introduced gas may alter the mean number, density, or temperature of said metastable atoms.

In a departure from prior art, one or more beams of laser radiation [108, 109, 110] may be transmitted through the discharge vessel [102], configured radially or axially or at any other orientation. These beams may optionally be used during either “Normal Mode” or during “Cold Ion Mode” according to various laser cooling and trapping techniques to shape or increase the phase space density of the beam of metastable atoms [111] emitted from the plasma vessel.

In another embodiment, used in Normal Mode operation, the beams of laser radiation [108, 109,110] are configured to instead alter the velocity or spatial distribution of metastable atoms within the plasma vessel. The generation of ions in an ICP often results from the ionization a metastable atoms; by cooling or compressing the metastable atoms in the ICP, the distribution of ions emitted from the discharge vessel [102] may have an enhanced brightness.

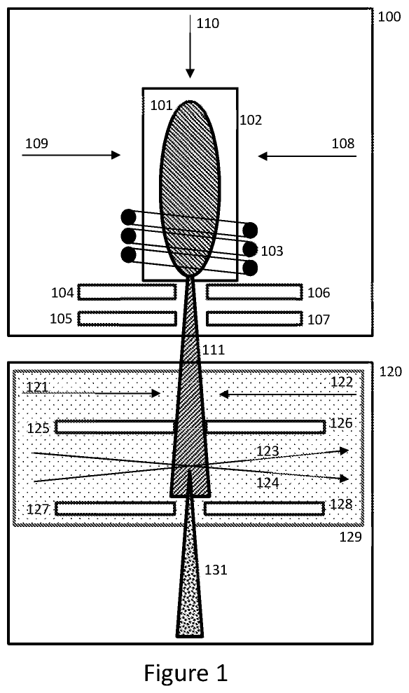

Additionally, a laser-cooling and photoionization stage [120] may be configured to receive the beam of metastable atoms [111] from the inductively coupled plasma ion source [100] (FIG. 1 shows an embodiment where electrodes 104-107 are biased to suppress the emission of ions from the ICP). Stage 102 is central to the operation of the ion source in Cold-Ion Mode. Stage 102 is positioned to receive the beam of metastable atoms effusively emitted from the discharge vessel [102]. One or more beams of laser radiation [121, 122] may then be applied to the beam of metastable atoms [111] in order to cool, compress laterally, deflect, or in general apply forces or manipulate the internal state of the atoms in the beam.

A magnetic field [129] may also be introduced in the [120] region to mediate the interaction between the laser beams and the metastable atoms. In addition, a magnetic field that varies in space may optionally be used directly to apply a conservative force-field to the atoms in the beam; for example a magnetic field with a gradient in a given direction will deflect the beam along that axis, while a field with a radial gradient would focus or defocus the metastable atom beam.

To create ions [131], one or more beams of laser radiation [123, 124] may be applied to the beam of metastable atoms [111] and configured to ionize the atoms. Configured here means tuning the beam's shape, intensity, frequency to optimize brightness and minimize the energy spread of the ion source. The ionization may be performed in a number of ways including resonant photoionization, non-resonant photoionization, and excitation to a Rydberg state that subsequently ionizes in an electric field that may differ from the field where the excitation occurred, see, e.g., U.S. Pat. No. 10,020,156 B2.

To accelerate the ions [131] created from the photoionized metastable atoms, one or more electrodes [125-128] may be configured spatially and have bias voltages applied to them to create an electric field in the region containing the ions.

The electrodes [125-128] may also be configured to provide a specific electric field (including zero field) necessary to facilitate the photoionization or Rydberg excitation process. Furthermore, the electrodes may be configured to provide more than one electric field or an electric field gradient as needed to facilitate ionization, as in the case of Rydberg excitation, or in shaping the ion beam for integration into a focused ion beam system's probe-forming optics.

The combined set of electrodes [104-107,125-128], as well as the coils or magnets producing static magnetic fields [129] compose the set of Charged Particle Optics in the system. Charged Particle Optics is defined herein to mean the set of physical objects controlling the acceleration of charged particles in their vicinity. Charged Particle Optics include, but are not limited to sets of conductive materials to which voltages are applied to create electric fields, e.g. electrodes, sets of current-carrying wires, or permanent magnets which generate magnetic fields.

### REFERENCES

1. U.S. Pat. No. 8,829,468 B2; MAGNETICALLY ENHANCED, INDUCTIVELY COUPLED PLASMA SOURCE FOR A FOCUSED ION BEAM SYSTEM
2. P. Chabert, N. Braithwaite. Physics of Radio Frequency Plasmas. Cambridge University Press (2011). ISBN 978-0-521-76300-4
3. U.S. Pat. No. 10,020,156 B2; RESONANT ENHANCEMENT OF PHOTOIONIZATION OF GASEOUS ATOMS
4. Y Hayashi et al. 2009 J. Phys. D: Appl. Phys. 42 145206. DOI 10.1088/0022-3727/42/14/145206

1. An ion source system, comprising:
a. an inductively coupled plasma (ICP) source, wherein metastable atoms and ions are generated within a plasma vessel;
b. a first mode and a second mode for producing an ion beam from the metastable atoms and the ions generated in the plasma vessel;
c. wherein the first mode further comprises
1. metastable atoms emitted from the plasma vessel;
2. one or more beams of laser radiation configured to excite the emitted metastable atoms to form ions;
3. charged particle optics configured to accelerate the emitted or extracted ions to form the ion beam;
d. wherein the second mode further comprises
1. ions emitted or extracted from the plasma vessel;
2. charged particle optics configured to accelerate the emitted or extracted ions to form the ion beam.
e. charged particle optics configured to condition the ion beam for use in focused ion beam instrumentation.

2. The system of claim 1, further comprising one of more beams of laser radiation configured to cool or compress the metastable atoms emitted from the plasma vessel.

3. The system of claim 2, further comprising a magnetic field applied in the vicinity of the one of more beams of laser radiation configured to cool or compress the metastable atoms emitted from the plasma vessel.

4. The system of claim 1, further comprising one or more beams of laser radiation applied to the metastable atoms contained inside the plasma vessel.

5. The system of claim 4, further comprising a magnetic field inside the plasma vessel configured to mediate the interaction of the metastable atoms and the one of more beams of laser radiation applied to the metastable atoms contained inside the plasma vessel.

6. The system in claim 1, wherein the beams of laser radiation excite a resonant ionization process in the electric field

7. The system in claim 1, wherein the beams or laser radiation excite the metastable atoms to Rydberg states that subsequently ionize in the electric field.

8. The system in claim 1, further comprising the introduction of an additional gas species to the plasma vessel to enhance the production of metastable atoms.

9. An ion source system comprising:
f. an inductively coupled plasma (ICP) source, wherein metastable atoms and ions are generated within a plasma vessel;
g. one or more beams of laser radiation configured to cool or compress the metastable atoms contained inside the plasma vessel;
h. ions emitted or extracted from the plasma vessel;
i. charged particle optics configured to accelerate the emitted or extracted ions to form the ion beam.

10. The system of claim 9, further comprising a magnetic field inside the plasma vessel configured to mediate the interaction of the metastable atoms and the one of more beams of laser radiation applied to the metastable atoms contained inside the plasma vessel.

11.-19. (canceled)

20. An ion source comprising:
j. an inductively coupled plasma (ICP) source comprising:
1. a plasma discharge vessel containing a gas and having a gas inlet and a plasma outlet;
2. an antenna adjacent said discharge vessel and configured to receive an RF current;
3. a plurality of electrodes arranged adjacent said plasma outlet;
k. a laser cooling and photoionization stage, comprising:
1. a metastable atom inlet configured to receive a beam of metastable atoms from said inductively coupled plasma source;
2. a first set of laser emitters each configured to direct a laser beam into said beam of metastable atoms to cool and/or condense said beam of metastable atoms;
3. a second set of laser emitters each configured to direct a laser beam into said beam of metastable atoms to photoionize a population of said metastable atoms to produce a population of ions;
4. a plurality of electrodes arranged adjacent said beam of metastable atoms configured to produce an electric field that converts said population of ions into an ion beam;

21. An ion source according to claim 20, further comprising a plurality of laser emitters each configured to direct a laser beam into said plasma discharge vessel.

22. An ion source according to claim 20, further comprising a plurality of permanent magnets configured to produce a magnetic field inside said plasma discharge vessel.

23. An ion source according to claim 20, further comprising a plurality of current-carrying wires configured to produce a magnetic field inside said plasma discharge vessel.

24. An ion source according to claim 20, further comprising a plurality of permanent magnets configured to produce a magnetic field in the vicinity of said beam of metastable atoms.

25. An ion source according to claim 20, further comprising a plurality of current-carrying wires configured to produce a magnetic field in the vicinity of said beam of metastable atoms.

26. An ion source according to claim 20, wherein the second set of laser emitters is configured to excite a resonant photoionization process in said electric field

27. An ion source according to claim 20, wherein the second set of laser emitters is configured to excite said metastable atoms to a Rydberg state that subsequently ionizes in said electric field

28. An ion source according to claim 20, further comprising a second gas contained in the plasma discharge vessel.

29.-37. (canceled)
